(19) United States
(12) Patent Application Publication
(10) Pub. No.: US 2017/0114979 A1
(43) Pub. Date: Apr. 27, 2017

(54) LENS AND LIGHT-EMITTING DEVICE MODULE COMPRISING THE SAME

(71) Applicant: LG INNOTEK CO., LTD., Seoul (KR)

(72) Inventors: Min Soo KANG, Seoul (KR); Kwang Ho KIM, Seoul (KR)

(73) Assignee: LG INNOTEK CO., LTD., Seoul (KR)

(21) Appl. No.: 15/128,811

(22) PCT Filed: Mar. 24, 2015
(86) PCT No.: PCT/KR2015/002862

§ 371 Date: Sep. 23, 2016

(30) Foreign Application Priority Data
Mar. 24, 2014 (KR) 10-2014-0034118
May 16, 2014 (KR) 10-2014-0058973

(51) Int. Cl. F21V 5/04; F21V 19/00; F21V 7/04; H01L 33/62

(52) U.S. Cl. CPC F21V 5/04; H01L 33/62; F21V 19/0025; F21V 7/04; G09G 3/36

(57) ABSTRACT

An embodiment provides a lens for changing the path of light incident from a light source, the lens comprising: region 1 which faces a light source and has a concave section formed thereon; and region 2 which faces region 1 and has a central region concave in the direction of region 1, wherein the surface of the concave section comprises: region 1-1 facing the center of the light source; region 1-3 formed at the edge; and region 1-2 formed between region 1-1 and region 1-3, the curvatures of region 1-1, region 1-2 and region 1-3 being different from one another.

### CROSS REFERENCE TO RELATED APPLICATION

This application claims priority under 35 U.S.C. §119 to Korean Patent Application No. 10-2014-0034118, filed in Korea on 24 Mar. 2014 and No. 10-2014-0058973, filed in Korea on, 16 May 2014, which are hereby incorporated in its entirety by reference as if fully set forth herein.

### TECHNICAL FIELD

Embodiments relate to a lens and a light-emitting device including the same, and more particularly, to widening a light emission angle of the light-emitting device and improvement of luminous efficacy of a backlight unit.

### BACKGROUND

Group III-V compound semiconductors, such as GaN and AlGaN, are widely used in optoelectronics and electronics due to many advantages thereof, such as easily controllable wide band gap energy.

In particular, light-emitting devices, such as light-emitting diodes or laser diodes, which use group III-V or II-VI compound semiconductors, are capable of emitting visible and ultraviolet light of various colors such as red, green, and blue owing to development of device materials and thin film growth techniques. These light-emitting devices are also capable of emitting white light with high luminous efficacy through use of a fluorescent substance or color combination and have several advantages of low power consumption, semi-permanent lifespan, fast response speed, safety, and environmental friendliness as compared to conventional light sources such as fluorescent lamps and incandescent lamps.

Accordingly, application sectors of the light-emitting devices are expanded to transmission modules of optical communication means, light-emitting diode backlights to replace cold cathode fluorescence lamps (CCFLs) which serve as backlights of liquid crystal display (LCD) apparatuses, white light-emitting diode lighting apparatuses to replace fluorescent lamps or incandescent lamps, vehicular headlamps, and traffic lights.

The LCD display device includes a TFT substrate and a color filter substrate facing each other, with which a liquid crystal layer is interposed therebetween. The LCD display device which is not self-illuminated may display an image using light generated from a backlight unit.

When a light-emitting device package is used as a light source of the LCD display device, the LCD display device may be classified into a side-edge type and a direct type according to disposition of the light source. In the case of the direct type, since a light guide plate may be omitted, the LCD display device may be slim and lightweight. However, since light emitted from each light-emitting device package is insufficiently provided to an optical sheet or the liquid crystal layer, light emitted from the other light-emitting device package adjacent to a target light-emitting device package interferes with light from emitted from the target light-emitting device package thereby, generating mura.

As a distance between the light-emitting device package and the optical sheet is increased, interference and generation of mura may be reduced. However, there is a problem in that a thickness of the LCD display device is increased.

### SUMMARY

In one embodiment, a lens for changing a path of light incident from a light source includes a first region facing the light source, the first region having a concave part formed thereon, and a second region facing the first region, the second region having a central portion which is concave toward the first region, wherein the concave part has a surface including a (1-1)th region facing a center of the light source, a (1-3)th region at an edge thereof, and a (1-2)th region between the (1-1)th region and the (1-3)th region, and the (1-1)th region, the (1-2)th region, and the (1-3)th region have different curvatures.

The (1-1)th region may be disposed at 0 to 45 degrees about a central axis, and the axis may extend from the light source to a center of the second region.

The (1-2)th region may be disposed at 30 to 80 degrees about a central axis, and the (1-3)th region may be disposed at 60 to 90 degrees about a central axis.

The (1-1)th region, the (1-2)th region, and the (1-3)th region may have positive curvatures or negative curvatures.

The (1-1)th region and the (1-3) the region may have positive curvatures, and the (1-2)th region has a negative curvature, or the (1-1)th region and the (1-3) the region may have negative curvatures, and the (1-2)th region has a positive curvature.

A ratio of a height of the lens to a height difference between an uppermost point and a lowermost point of the second region may be more than 1:0.7 and less than 1:1.

In another embodiment, a lens changing a path of light incident from a light source include a first region facing the light source, the first region having a concave part formed thereon, a second region facing the first region, the second region having a central portion which is concave toward the first region, wherein, the concave part has a surface including a (1-1)th region facing a center of the light source, a (1-3)th region at an edge thereof, and a (1-2)th region between the (1-1)th region and the (1-2)th region, and the (1-1)th region, the (1-2)th region, and the (1-3)th region have different refraction angles.

Light passing through the (1-1)th region after being emitted from the light source may be refracted toward a central axis.

Light passing through the (1-2)th region after being emitted from the light source may be refracted toward a central axis.

Light passing through the (1-3)th region after being emitted from the light source may be refracted toward a central axis.

The refraction angle of light which passes through the (1-2)th region after being emitted from the light source may be largest.

Among light proceeding to the second region after being refracted at the first region, an angle between light passing through the (1-1)th region and an axis may be smallest.

Among light proceeding to the second region after being refracted at the first region, an angle between light passing through the (1-3)th region and an axis may be largest.

The refraction angle of light which passes through the (1-3)th region after being emitted from the light source may be smallest.

A distributed Bragg reflector (DBR) or an omni-directional reflector (ODR) may be disposed at a surface of a light emitting surface of the lens described above or a region spaced from the surface.

In another embodiment, a light-emitting device module includes a first frame and a second frame, a light-emitting device disposed at a body, the light-emitting device being electrically connected to the first frame and the second frame, a molding part surrounding the light-emitting device, and a lens changing a path of light incident from the light source, wherein a reflective layer is disposed on a light emitting surface of the lens.

The lens may include a first region facing the light source, the first region having a concave part formed thereon, and a second region facing the first region, the second region having a central portion which is concave toward the first region, wherein the concave part may have a surface including a (1-1)th region facing a center of the light source, a (1-3)th region at an edge thereof, and a (1-2)th region between the (1-1)th region and the (1-2)th region, and the (1-1)th region, the (1-2)th region, and the (1-3)th region may have different curvatures.

The lens may include a first region facing the light source, the first region having a concave part formed thereon, and a second region facing the first region, the second region having a central portion which is concave toward the first region, wherein the concave part may have a surface including a (1-1)th region facing a center of the light source, a (1-3)th region at an edge thereof, and a (1-2)th region between the (1-1)th region and the (1-2)th region, and the (1-1)th region, the (1-2)th region, and the (1-3)th region may have different refraction angles. The reflective layer may include a distributed Bragg reflector (DBR) or an omni-directional reflector (ODR).

### BRIEF DESCRIPTION OF THE DRAWINGS

FIG. 1 is a view illustrating a lens of a first embodiment;

FIG. 2 is a view illustrating a size of the lens of FIG. 1;

FIGS. 2B to 2F are views concretely illustrating region “A” of FIG. 1;

FIGS. 3A to 3C are perspective views and a side cross-sectional view illustrating the lens;

FIGS. 4A and 4B are views illustrating paths of light of a light-emitting device module;

FIGS. 5A to 5C are views illustrating a light-emitting device module of a first embodiment;

FIGS. 6A to 6C are views illustrating a light-emitting device module of a second embodiment;

FIGS. 7A and 7B are views illustrating a light-emitting device module of a third embodiment;

FIGS. 8A to 8C are views illustrating a light-emitting device module of a fourth embodiment;

FIGS. 9A and 9B are cross-sectional views illustrating light-emitting device modules of a fifth embodiment and a sixth embodiment, respectively;

FIGS. 10A and 10B are views illustrating reflective layers according to embodiments of FIGS. 9A and 9B, respectively;

FIGS. 11A and 11B illustrates paths of light of the light-emitting device modules of FIGS. 9A and 9B, respectively;

FIG. 12A is a view illustrating a size of the lens of FIG. 9A;

FIGS. 12A to 12D and FIGS. 13A to 13D are views illustrating various embodiments of the lenses of FIGS. 9A and 9B;

FIGS. 14 and 15 are views illustrating a display device including the light-emitting device module;

FIG. 16 is a view illustrating improvement of mura in the light-emitting device module according to embodiments; and

FIGS. 17A and 17B are views illustrating improvement of a dark part in a backlight unit of the display device according to embodiments.

### DESCRIPTION OF SPECIFIC EMBODIMENTS

Hereinafter, exemplary embodiments to concretely realize the above objects will be described in detail with reference to the accompanying drawings.

In the following description of the embodiments, it will be understood that, when each element is referred to as being formed “on” or “under” the other element, it can be directly “on” or “under” the other element or be indirectly formed with one or more intervening elements therebetween. In addition, it will also be understood that “on” or “under” the element may mean an upward direction and a downward direction of the element.

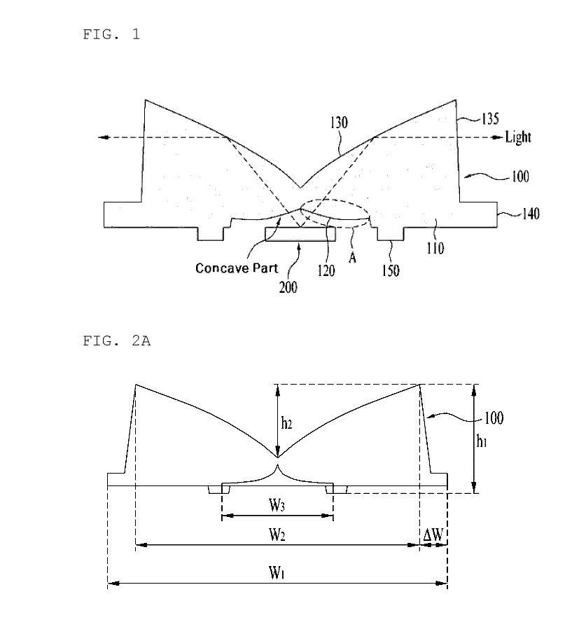

FIG. 1 is a view illustrating a lens of a first embodiment.

The lens 100 may be disposed at a light source of a light-emitting device package 200 to change a path of light incident from a light source. The lens 100 may be formed of a transparent material. For example, the lens 100 may be formed of polycarbonate or a silicon resin.

A concave part may be formed at a first region 120, namely, a light incident surface, facing the light-emitting device package 200 employed as a light source in the lens 100 according to the illustrated embodiment. At least part of the light-emitting device package 200 may be disposed in the concave part in an inserted manner.

A central region of a second region 130 facing the first region 120 may be concavely formed toward the first region 120. Thereby, light may be completely reflected as illustrated. In addition, a third region 135 of a side surface of the lens 100 may function as a light emitting surface, through which a part of light incident from the first region 120, namely, the light incident surface, and light reflected from the second region 130, namely, a total reflective surface, pass.

Protrusions 140 may be formed at a lower part of the third region 135. At least three supporters 150 may be formed at a lower part of the lens 100. The supporters 150 may function to support the lens 100 at a bottom chassis when the lens 100 is fixed to a display device, which will be described later.

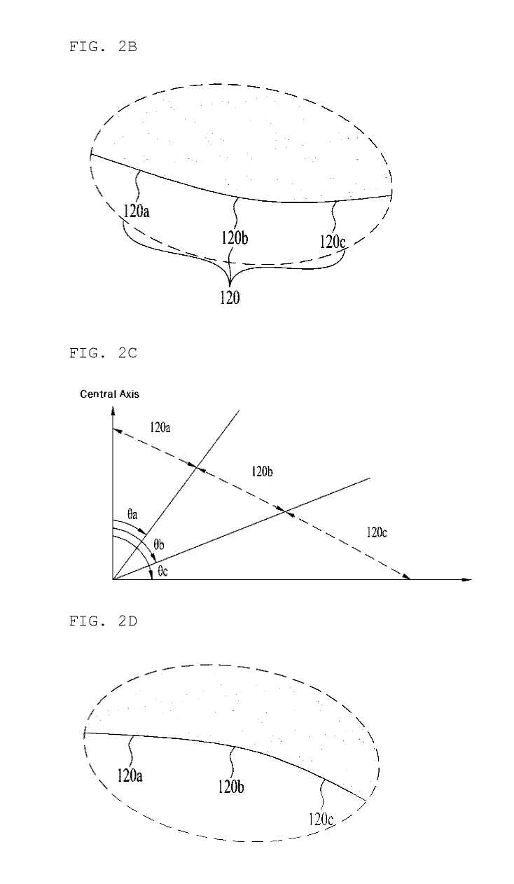

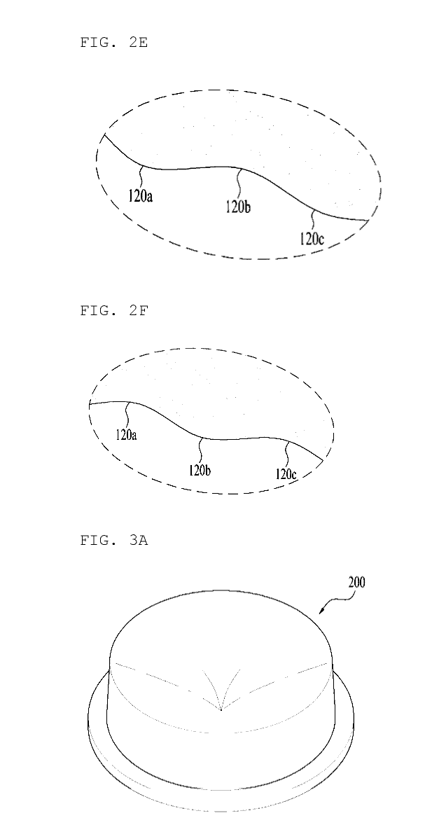

FIG. 2 is a view illustrating a size of the lens of FIG. 1.

A ratio of a height h1 of the lens 100 to a height difference h2 between an uppermost point and a lowermost point of the second region 130 may be 1:0.7 to 1:1. The height h1 of the lens 100 may be a vertical distance from a lower surface of each supporter 150 to the uppermost point of the second region 130 of the lens 100. The height difference h2 between the uppermost and lowermost points of the second region 130 may be a depth in which the second region 130 is concavely formed. In detail, the height difference h2 may be a vertical distance from an uppermost region of the second region 130 to a lowermost region of the concave part.

When the ratio of the height h1 of the lens 100 to the height difference h2 between the uppermost and lowermost points of the second region 130 is less than 1:0.7, the amount of light completely reflected at the second region 130 of light incident from the light incident surface may be decreased.

When the ratio of the height h1 of the lens 100 to the height difference h2 between the uppermost and lowermost points of the second region 130 is 1:1, the second region 130 of the lens 100 may be flat. When the ratio of the height h1 of the lens 100 to the height difference h2 between the uppermost and lowermost points of the second region 130 is greater than 1:1, the second region 130 of the lens 100 may be flat or be convex at the central portion.

A horizontal length W2 of the lens 100 may be greater than a distance W1 between the protrusions 140. For example, the horizontal length W2 of the lens 100 may be 18 millimeters and the distance W1 between the protrusions 140 may be 21.5 millimeters. A protruded width ΔW of each protrusion 140 may be one-half of a difference value of the distance W1 between the protrusions 140 and the horizontal length W2 of the lens 100, as illustrated above. When the width ΔW is small, it may be not enough to support an injected object during an injection process of the lens 100. When the width ΔW is large, a horizontal size of the entire lens 100 may be increased in comparison with a region for changing the path of light. The protrusions 140 may be formed to support the injected object during the injection process of the lens 100.

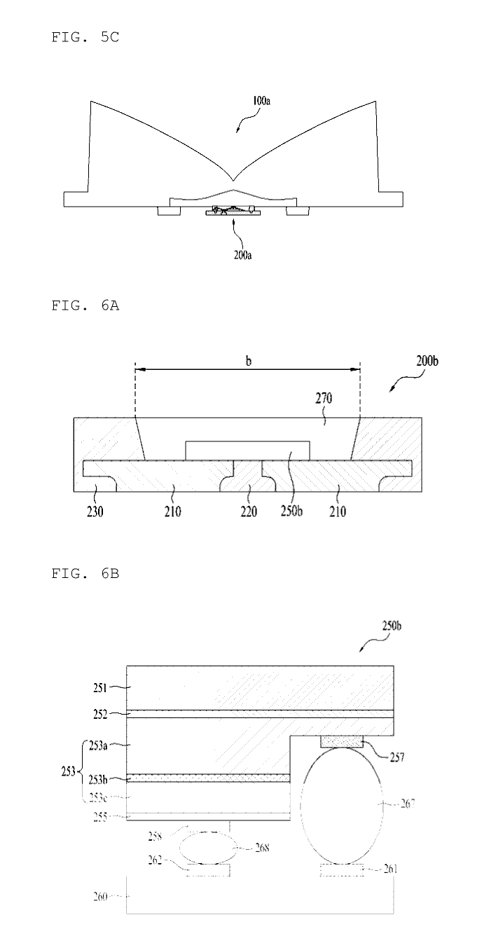

A width W3 of the concave part formed at the lower part of the lens 100 may be greater than a width of a light emitting part of the light-emitting device package. Herein, the width of the light emitting part of the light-emitting device package may be, for example, a width “a” as illustrated in FIG. 5A.

FIGS. 2B to 2F are views concretely illustrating region “A” of FIG. 1.

The first region 120 where light is incident from the light source may be a surface of a cavity. The first region 120 may include a (1-1)th region 120a facing a center of the light source, a (1-3)th region 120c of an edge of the first region 120, and a (1-2)th region 120b between the (1-1)th region 120a and the (1-3)th region 120c. The (1-1)th region 120a, the (1-2)th region 120b, and the (1-3)th region 120c may have different curvatures.

When a virtual line connected to a center of the second region 130 from the light source is referred at as a central axis, an angle θa between the (1-1)th region 120a and the central axis may be 0 to 45 degrees, an angle θb between the (1-2)th region 120b and the central axis may be 30 to 80 degrees, and an angle θc between the (1-3)th region 120c and the central axis may be 60 to 90 degrees.

The (1-1)th region 120a, the (1-2)th region 120b, and the (1-3)th region 120c may have curvatures instead of being flat. As illustrated, the regions may have different curvatures. Furthermore, each region may have a positive curvature or a negative curvature. Since the curvatures of (1-1)th region 120a, the (1-2)th region 120b, and the (1-3)th region 120c are very similar, it may be difficult to recognize difference of the curvatures in FIG. 2B.

For example, as illustrated in FIG. 2B, the (1-1)th region 120a, the (1-2)th region 120b, and the (1-3)th region 120c may have positive curvatures. As illustrated in FIG. 2D, the (1-1)th region 120a, the (1-2)th region 120b, and the (1-3)th region 120c may have negative curvatures. Furthermore, as illustrated in FIG. 2E, the (1-1)th region 120a and the (1-3)th region 120c may have positive curvatures, and the (1-2)th region 120b may have a negative curvature. As illustrated in FIG. 2F, the (1-1)th region 120a and the (1-3)th region 120c may have negative curvatures, and the (1-2)th region 120b may have a positive curvature.

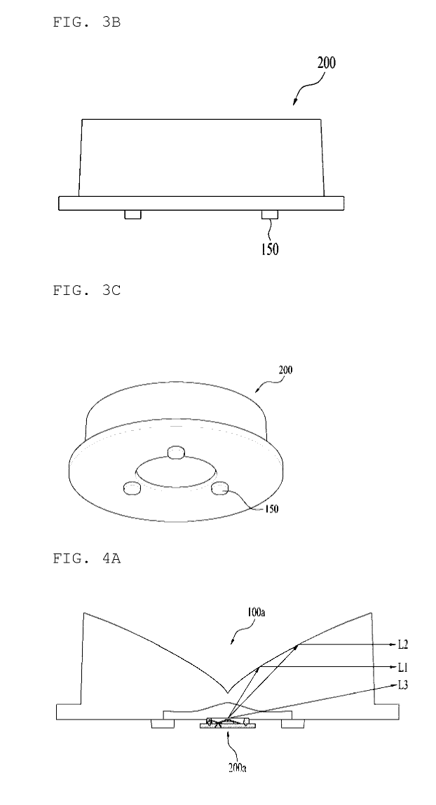

FIGS. 3A to 3C are perspective views and a side cross-sectional view illustrating the lens. As illustrated, a center of an upper surface of the lens 100 may have a concave shape.

In FIG. 3B, two supporters 150 may be provided at the lens, but, as illustrated in FIG. 3C, three supporters 150 may be provided at the lens. Four supporters 140 or more may be provided. FIG. 3C illustrates three supporters 150 arranged in a triangular manner, but the number and arrangement of the supporters may be varied. Width, thickness, and height of a supporter of the supporters may be differently formed, and may not be limited thereto.

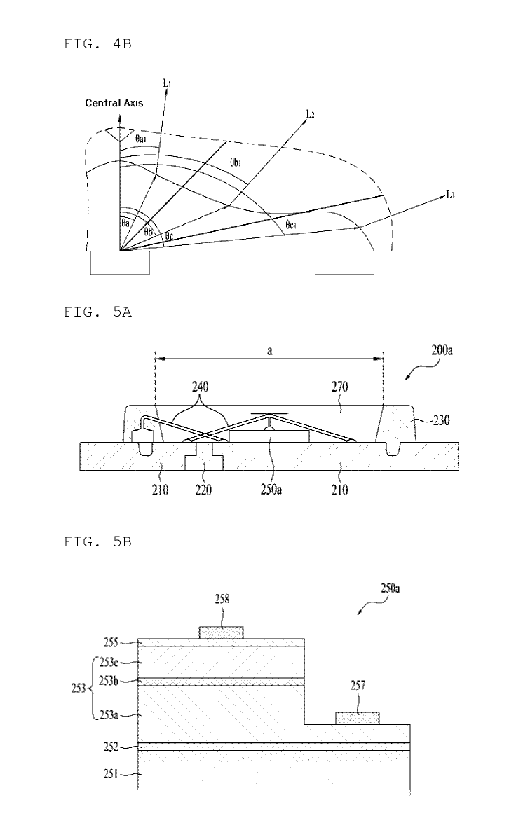

FIGS. 4A and 4B are views illustrating path of lights of a light-emitting device module.

The light-emitting device module may include a light-emitting device package 200a and a lens 100a. In FIG. 4A, the light-emitting device package 200a and the lens 100a according to an embodiment illustrated in FIGS. 5A to 5C are described, but the light-emitting device package and the lens may be applied to other embodiments.

Light emitted from the light-emitting device package 200a, namely, a light source, may be incident to the first region, namely, a light incident surface. The first region, as illustrated above, may include the (1-1)th region facing the light source, the (1-3)th region of the edge of the first region, and the (1-2)th region between the (1-1)th region and the (1-3)th region.

FIG. 4A illustrates light L1 passing through the (1-1)th region, light L2 passing through the (1-2)th region, and light L3 passing through the (1-3)th region. As illustrated in FIG. 4B, light L1 passing through the (1-1)th region, light L2 passing through the (1-2)th region, and light L3 passing through the (1-3)th region may have different refraction angles.

In FIG. 4B, light L1 passing through the (1-1)th region after being emitted from the light source may be refracted toward the central axis. An angle θa between light L1 passing through the (1-1)th region before refraction and the central axis may be greater than an angle θa1 between light L1 after refraction and the central axis. Herein, the “central axis” is the same as the central axis as described in FIG. 2C.

Furthermore, light L2 passing through the (1-2)th region after being emitted from the light source may be refracted toward the central axis. An angle θb between light L2 passing through the (1-2)th region before refraction and the central axis may be greater than an angle θb1 between light L2 after refraction and the central axis.

In addition, light L3 passing through the (1-3)th region after being emitted from the light source may be refracted toward the central axis. An angle θc between light L3 passing through the (1-3)th region before refraction and the central axis may be greater than an angle θc1 between light L3 after refraction and the central axis.

As described above, an angle change of the angle between light L1, L2, and L3 and the central axis before refraction and the angle between light L1, L2, and L3 and the central axis after refraction is defined as a refraction angle. Herein, the refraction angle of light L2 passing through the (1-2)th region after being emitted from the light source may be largest, and the refraction angle of light L3 passing through the (1-3)th region may be smallest.

In addition, among light L1, L2, and L3 refracted from the first region to proceed to the second region, a refraction angle θa1 between light L1 passing through the (1-1)th region and the central axis may be smallest.

Furthermore, among light L1, L2, and L3 refracted from the first region to proceed to the second region, a refraction angle θc1 between light L3 passing through the (1-3)th region and the central axis may be largest.

FIGS. 5A to 5C are views illustrating a light-emitting device module of a first embodiment.

The light-emitting device module may include a light-emitting device package 200a and a lens 100a. Embodiments which will be described later may be the same as the above light-emitting device module. In the light-emitting device package 200a, a first lead frame and a second lead frame may be electrically separated by an insulator 220. A light-emitting device 250a may be electrically connected to the first lead frame and the second lead frame by bonding wires 240, respectively. A sidewall 230 may be disposed at a circumference of the light-emitting device 250a to be spaced from the light-emitting device 250a. A molding part 270 may be formed in the sidewall 230. The lens 100a will be described in FIG. 5C.

A package body may be formed by the sidewall 230 and the insulator 220 and may be formed of a silicon material, a synthetic resin, or a metallic material. The first lead frame and the second lead frame may reflect light emitted from the light-emitting device 250a to improve luminous efficacy. The first lead frame and the second lead frame may radiate heat generated by the light-emitting device 250a. In addition, a separate reflector (not shown) may be disposed on the first lead frame and the second lead frame to reflect light emitted from the light-emitting device 250a, without being limited thereto.

The molding part 270 may surround the light-emitting device 250a to protect the light-emitting device 250a. The molding part 270 may include a fluorescent substance (not shown) to convert a wavelength of light emitted from the light-emitting device 250a.

In the light-emitting device package 200a of FIG. 5A, a region, from which light is emitted may be a cavity defined by the first lead frame 210, the second lead frame 210, and the sidewall 230. For example, a width a of an entrance of the cavity may be 1.9 to 2.3 millimeters. The width a of the entrance of the cavity may not be limited thereto and may have different values according to sizes of the light-emitting device package 200a or the lens.

FIG. 5B illustrates the light-emitting device of FIG. 5A.

The light-emitting device 250a may be a horizontal light-emitting device. The light-emitting device 250a may include a substrate 251, a buffer layer 252 disposed on the substrate 251, a light-emitting structure 253 including a first conductive type semiconductor layer 253a, an active layer 253b, and a second conductive type semiconductor layer 253c, a transparent conductive layer 255, a first electrode 257 disposed on the first conductive type semiconductor layer 253a, and a second electrode 258 disposed on the second conductive type semiconductor layer 253b. As illustrated in FIG. 5B, the buffer layer 252 may be disposed between the substrate 251 and the light-emitting structure 253, without being limited thereto.

The substrate 251 may be formed of a material suitable for growth of a semiconductor material or a carrier wafer. The substrate 251 may be formed of a material having high thermal conductivity and may include a conductive substrate or an insulation substrate. For example, the substrate 251 may utilize at least one of sapphire (Al₂O₃), SiO₂, SiC, Si, GaAs, GaN, ZnO, GaP, InP, Ge, and Ga₂O₃.

The substrate 251 may be formed of sapphire. When the light-emitting structure 253 including GaN or AlGaN is disposed on the substrate 251, a lattice mismatch between GaN or AlGaN and sapphire is very great and a coefficient of thermal expansion therebetween is very great, thereby generating defects such as melt-back, cracking, pitting, poor surface morphology, and dislocations, which aggravate crystallizability. To this end, the buffer 252 may be formed of AlN and may be disposed between the substrate 251 and the light-emitting structure 253.

The first conductive type semiconductor layer 253a may be disposed on the substrate 251 and may be formed of group III-V or II-VI compound semiconductors. The first conductive type semiconductor layer 253a may be doped with a first conductive type dopant. The first conductive type semiconductor layer 253a may be formed of a semiconductor material having a composition of AlₓIn_{y}Ga_{(1-x-y)}N (0≦x≦1, 0≦y≦1, 0≦x+y≦1), i.e. any one or more materials selected from among AlGaN, GaN, InAlGaN, AlGaAs, GaP, GaAs, GaAsP, and AlGaInP.

When the first conductive type semiconductor layer 253a is an n-type semiconductor layer, the first conductive type dopant may include an n-type dopant such as Si, Ge, Sn, Se, and Te. The first conductive type semiconductor layer 253a may have a single layer or multilayer form, without being limited thereto.

The active layer 253b may be disposed on an upper surface of the first conductive type semiconductor layer 253a. The active layer 253b may include any one of a single-well structure, a multi-well structure, a single-quantum well structure, a multi-quantum well structure, a quantum dot structure and a quantum wire structure.

The active layer 253b may be include a well layer and a barrier layer, using a group III-V compound semiconductor, having a pair structure of any one or more of AlGaN/AlGaN, InGaN/GaN, InGaN/InGaN, AlGaN/GaN, InAlGaN/GaN, GaAs(InGaAs)/AlGaAs, and GaP(InGaP)/AlGaP, without being limited thereto. At this time, the well layer may be formed of a material having a smaller energy band gap than an energy band gap of the barrier layer.

The second conductive type semiconductor layer 253c may be disposed on the active layer 253b and may be formed of a compound semiconductor. The second conductive type semiconductor layer 253c may be formed of a compound semiconductor such as a group III-V or II-VI compound semiconductor and may be doped with a second conductive type dopant. The second conductive type semiconductor layer 253c may be formed of, for example, a semiconductor material having a composition of InₓAl_{y}Ga_{1-x-y}N (0≦x≦1, 0≦y≦1, 0≦x+y≦1), i.e. any one or more material selected from among AlGaN, GaNAlInN, AlGaAs, GaP, GaAs, GaAsP, and AlGaInP. The second conductive type semiconductor layer 253c may be doped with the second conductive type dopant. When the second conductive type semiconductor layer 253c is a p-type semiconductor layer, the second conductive type dopant may be a p-type dopant such as Mg, Zn, Ca, Sr, and Ba. The second conductive type semiconductor layer 253c may have a single layer or multilayer form, without being limited thereto.

In the illustrated embodiment, the first conductive type semiconductor layer 253a may be an n-type semiconductor layer, and the second conductive type semiconductor layer 253c may be a p-type semiconductor layer. Alternatively, the first conductive type semiconductor layer 253a may be a p-type semiconductor layer, and the second conductive type semiconductor layer 253c may be an n-type semiconductor layer. Furthermore, a third conductive type semiconductor layer may be formed on the second conductive type semiconductor layer 253c having an opposite conductive type dopant to the second conductive type. Accordingly, the light emitting structure 253 may be implemented in any one structure selected from among an n-p junction structure, a p-n junction structure, an n-p-n junction structure, and a p-n-p junction structure.

Although not illustrated, an electron blocking layer may be interposed between the active layer 253b and the second conductive semiconductor layer 253c. The electron blocking layer may have a superlattice structure. For example, the superlattice structure may include an AlGaN layer doped with a second conductive type dopant, or may include a plurality of alternately arranged GaN layers having different aluminum composition ratios.

As the second conductive type semiconductor layer 253c, the active layer 253b, and a portion of the first conductive type semiconductor layer 253a are mesa-etched in a part of the light-emitting structure 253, a surface of the first conductive type semiconductor layer 253a may be exposed.

The first electrode 257 and the second electrode 258 may be disposed on the exposed surface of the first conductive type semiconductor layer 253a and the second conductive type semiconductor layer 253c, respectively. The first electrode 257 and the second electrode 258 may include at least one of aluminum (Al), titanium (Ti), chromium (Cr), copper (Cu), and gold (Au), and may have a single layer or multilayer form. In addition, the first electrode 257 and the second electrode 258 may be connected to each wire (not shown).

FIG. 5C illustrates the light-emitting device package 200a disposed at the lens 100a. The light-emitting device package 200a is inserted into the concave part formed at the light incident surface of the lower part of the lens 100a.

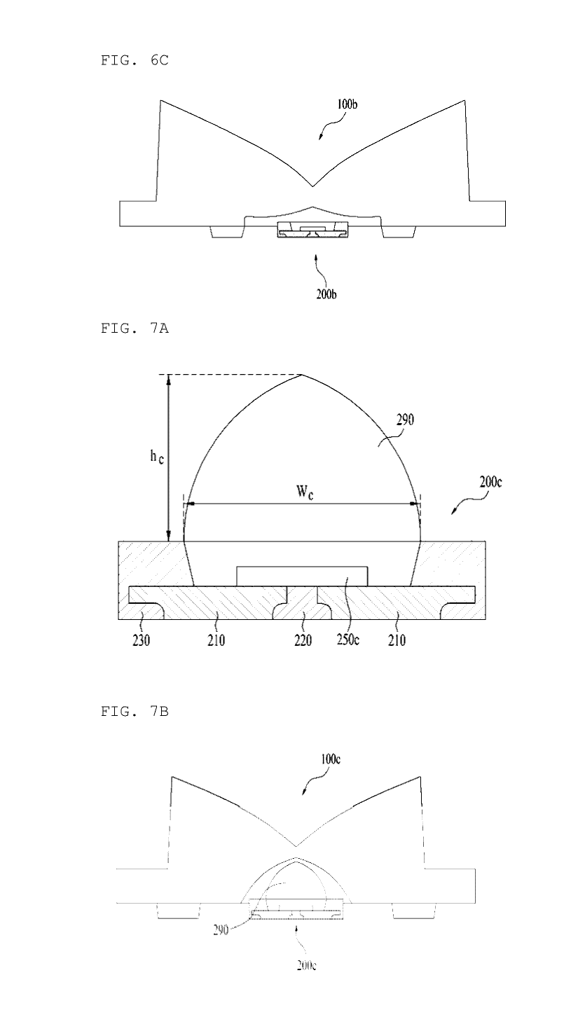

FIGS. 6A to 6C are views illustrating a light-emitting device module of a second embodiment.

The light-emitting device package 200b in FIG. 6A is similar to the embodiment illustrated in FIG. 5A but differs in that the light-emitting device 250b may be disposed to have a flip chip type structure, thereby omitting the wires. A vertical type light-emitting device or a horizontal type light-emitting device may be used as a light-emitting device 250b.

The first lead frame 210 and the second lead frame 210 may be electrically separated by the insulator 220. The sidewall 230 may form a package body. The first and second lead frames 210 may form the lower surface of the cavity. The molding part 270 may fill the cavity.

In FIG. 6A, the light-emitting device package 200b may have a flip chip type light-emitting device without the wires, which will be described later, thereby improving light-extraction efficiency. Accordingly, an area of light emitted from a surface of the light-emitting device package may become small. As illustrated, a width b of the entrance of the cavity, namely, a region where light is emitted may be, for example, 15 to 18 millimeters. The width of the entrance of the cavity is not limited thereto and may have different values according to the size of the light-emitting device package or the lens.

FIG. 6B illustrates the light-emitting device of FIG. 6A.

A first electrode pad 261 and a second electrode pad 262 may be disposed on a sub-mount 260. The first electrode pad 261 and the second electrode pad 262 may be bonded to the first electrode 257 and the second electrode 258 through bumps 267 and 268, respectively.

FIG. 6C illustrates the light-emitting device package 200b including the lens 100b. The light-emitting device package 200b may be inserted into the concave part formed at the light incident surface of the lower part of the lens 100b. A size of the concave part formed at the light incident surface may be identical to or different from the size of the cavity of FIG. 5C.

FIGS. 7A to 7C are views illustrating a light-emitting device module of a third embodiment.

The third embodiment differs from the other embodiments describe-above in that two lenses are disposed at a light-emitting device package 200c.

The light-emitting device package 200c in FIG. 7A is similar to the light-emitting device package illustrated in FIG. 6A. In FIG. 7A, the horizontal type light-emitting device 250a illustrated in FIG. 5A may be disposed, but a vertical type light-emitting device or a flip chip type light-emitting device may be used. A conic lens 290 is disposed on a light emitting surface of the cavity. To distinguish between the two lenses, the conic lens 290 may be referred to as a first lens and an upper lens 100c may be referred to as a second lens.

The conic lens 290 allows a luminous view angle of light emitted from the light-emitting device package to be narrowed. Thereby, an area of projected light may be reduced. As illustrated in FIG. 7B, the conic lens 290 have a size to be inserted into the concave part of the lower part of the lens. A width Wc of the conic lens 290 may be 2.1 millimeters or more. A height Hc thereof may be 1.2 to 1.5 millimeters. When the width Wc of the conic lens 290 is less than 2.1 millimeters, the luminous view angle of the entire light emitted from the light-emitting device package may be not reduced. When the height Hc is less than 1.2 millimeters, it may be not enough to narrow the luminous view angle. When the height Hc is greater than 1.5 millimeters, the concave part of the lower part of the lens may be formed too deeply to implement desired light characteristics.

In FIG. 7B, the conic lens 290 is disposed on the light-emitting device package 200c of FIG. 7A. The lens 100c is disposed on the conic lens 290. A concave part may be formed at the light incident surface of the lens 100c. The light-emitting device package 200c and the conic lens 290 may be inserted into the concave part. Accordingly, the size of the concave part may be greater than the size of the described-above embodiments.

In the light-emitting device package 200c according to this embodiment, the conic lens 290 is disposed at the lower part of the lens 100c such that light emitted from the light-emitting device package 200c passes through the conic lens 290, and, as such, the luminous view angle may be narrowed. Accordingly, light passing through the lens 100c may be laterally spread widely.

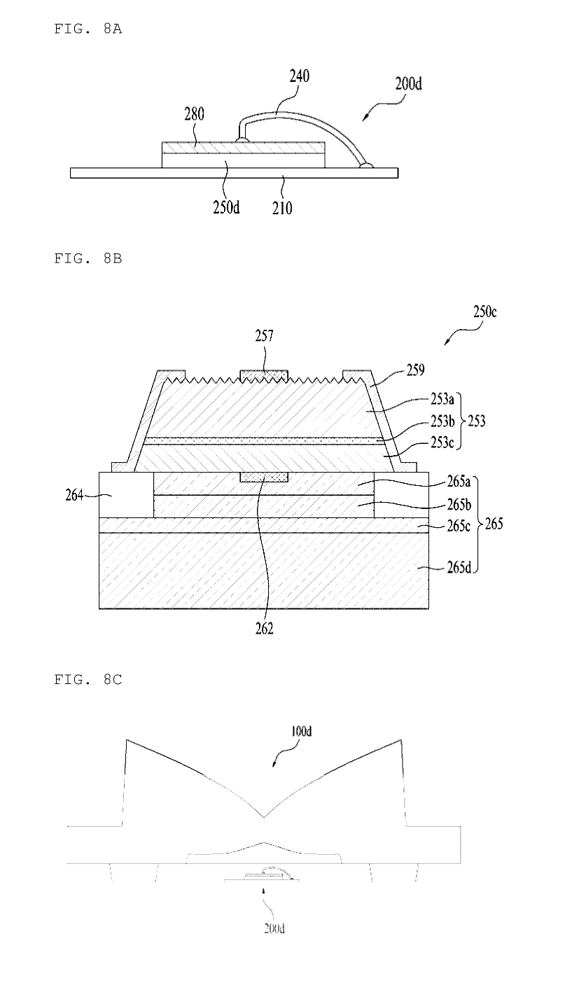

FIGS. 8A to 8C are views illustrating a light-emitting device module of a fourth embodiment. In the light-emitting device package according to this embodiment, the light-emitting device may have a chip on board (COB) type.

In light-emitting device package 200d, the light-emitting device 250d may be disposed on a lead frame 210 employed as a substrate. A fluorescent substance may be formed on the light-emitting device 250d using a conformal coating method. One electrode of the light-emitting device 250d may be electrically connected to the lead frame 210 through a wire 240.

The light-emitting device 250d may be the vertical type light-emitting device as illustrated in FIG. 8B, or may be a horizontal type light-emitting device or a flip chip type light-emitting device.

In the light-emitting device 250d according to this embodiment, the light-emitting structure 253 including the first conductive type semiconductor layer 253a, the active layer 253b, and the second conductive type semiconductor layer 253c is disposed on the second electrode 265. The composition of the light-emitting structure 253 is the same as the composition described above.

The second electrode 265 may be formed to include at least one of a bonding layer 265c disposed on a conductive support substrate 265d, a reflective layer 265b, and an ohmic layer 265a.

The conductive support substrate 265d may use a metal having high electrical conductivity. The conductive support substrate 265d may use a metal having high thermal conductivity to sufficiently radiate heat generated upon operation of the device. The conductive support substrate 256d may be formed of at least one selected from the group consisting of molybdenum (Mo), silicon (Si), tungsten (W), copper (Cu), and aluminum (Al) or alloys thereof. Furthermore, the conductive support substrate 256d may selectively include gold (Au), copper alloy (Cu alloy), nickel (Ni), copper-tungsten (Cu—W), and a carrier wafer (e.g. GaN, Si, Ge, GaAs, ZnO, SiGe, SIC, SiGe, Ga₂O₃).

In addition, the conductive support substrate 265d may have sufficient mechanical strength to be efficiently separated as a chip during a scribing process and a breaking process without causing bending of a nitride semiconductor device.

The bonding layer 265c may serve to bond the reflective layer 265b and the conductive support substrate 265d to each other. The reflective layer 265b may function as an adhesion layer. The bonding layer 265c may be formed of a material selected from the group consisting of gold (Au), tin (Sn), indium (In), aluminum (Al), silicon (Si), silver (Ag), nickel (Ni), and copper (Cu), or alloys thereof.

The reflective layer 265b may have a thickness of about 2500 angstroms. The reflective layer 265b may be a metal layer formed of molybdenum (Mo), aluminum (Al), silver (Ag), nickel (Ni), platinum (Pt), rhodium (Rh), or alloys including Al, Ag, Pt or Rh. Aluminum, silver, or the like may effectively reflect light emitted from the active layer 253b to significantly enhance light-extraction efficiency of a semiconductor device.

The light-emitting structure 253, in particular, the second conductive type semiconductor layer 253b has a low impurity doping concentration to have high resistance. Thereby, ohmic characteristics may be poor. The ohmic layer 265a may be formed by a transparent electrode to improve ohmic characteristics.

The ohmic layer 265a may have a thickness of about 200 angstroms. The ohmic layer 265a may be formed of at least one selected from among indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—Ga ZnO (AGZO), In—Ga ZnO (IGZO), ZnO, IrOx, RuOx, NiO, RuOx/ITO, Ni/IrOx/Au, Ni/IrOx/Au/ITO, Ag, Ni, Cr, Ti, Al, Rh, Pd, Ir, Sn, In, Ru, Mg, Zn, Pt, Au, and Hf, without being limited to these materials.

A current blocking layer 262 formed of an insulation material may be disposed below the light-emitting structure 253 to allow a current to uniformly flow in the entire region of the light-emitting structure 253. A channel layer 264 formed of an insulation material may formed below edges of the light-emitting structure 253.

A pattern may be formed at a surface of the light-emitting structure 253 to improve light-extraction efficiency. The surface of the light-emitting structure 253 at which the first electrode 257 is disposed may not be formed to have a concavo-convex surface.

A passivation layer 259 may be formed at a side surface of the light-emitting structure 253. The passivation layer 259 may be formed of an insulation material. For example, the insulation material may include a non-conductive material such as an oxide or a nitride, or a silicon oxide (SiO₂) layer, an oxynitride layer, or an aluminum oxide layer.

FIG. 8C illustrates the light-emitting package 200d including the lens 100d. The light-emitting device package 200d is inserted into the concave part formed at the light incident surface of the lower part of the lens 100d. A size of the concave part formed at the light incident surface may be the same as or different from the size of the concave part of FIG. 5C.

A reflective layer such as a distributed Bragg reflector (DBR) or an omni-direction reflector (ODR) may be disposed at a surface of the light emitting surface of the lens described above or a region spaced from the surface, and will be described later.

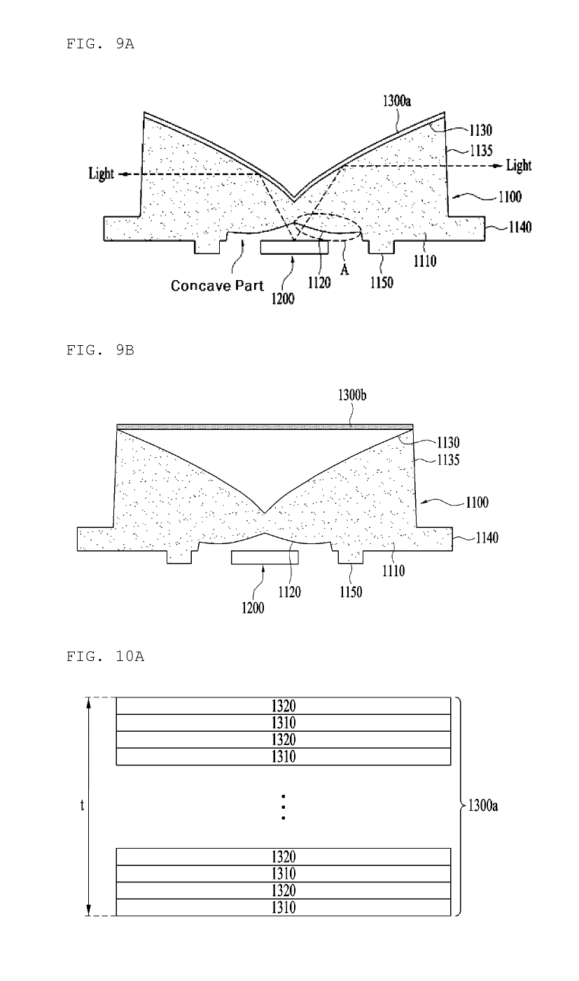

FIGS. 9A and 9B are cross-sectional views illustrating light-emitting device modules of a fifth embodiment and a sixth embodiment. In FIG. 9A, surface contact may be provided between a reflective layer 1300a and a surface of a lens 1100. On the other hand, in FIG. 9B, line contact may be provided between a reflective layer 1300b and the surface of the lens 1100.

In FIG. 9A, the lens 1100 may be disposed on a light source of the light-emitting device package 1200 to change a path of light incident from the light source. The lens 1100 may be formed of a transparent material. For example, the lens 1100 may be formed of polycarbonate or a silicon resin. In addition, a portion formed of polycarbonate or a silicon resin may be referred to as a body of the lens 1100, and may be different from a material of the reflective layer 1300a.

A concave part may be formed at a first region, namely, a light incident surface facing the light-emitting device package 1200, namely, a light source, in the lens 110. Thereby, at least part of the light-emitting device package 1200 may be inserted into the concave part.

A central region of a second region 1130 facing the first region 1120 may be concavely formed toward the first region 1120 to reflect light. The reflective layer 1300a having a uniform thickness is disposed on a surface of the second region 1130. The reflective layer 1300a, which will be described later, may be a DBR or an ODR. The thickness of the reflective layer 1300a is not limited thereto. For example, a part of the reflective layer 1300a may be thinner or thicker than the other parts.

A third region 1135 of a side surface of the lens 1100 may function as a light emitting surface, through which a part of light incident from the first region 1120, namely, the light incident surface, and light reflected from the second region 1130, namely, a reflective surface pass. Herein, the second region 1130 may be a total reflective surface where incident light is completely reflected.

Protrusions 1140 may be formed at a lower part of the third region 1135. At least three supporters 1150 may be formed at a lower part of the lens 1100. The protrusions 1140 may be formed to support the injected object during the injection process of the lens 1100. The supporters 1150 may function to support the lens 1100 at a bottom chassis when the lens 1100 is fixed to a display device, which will be described later.

The structure illustrated in FIG. 9B is similar to the structure of FIG. 9A, but disposition of a reflective layer 1300b is different. Configurations of the light-emitting device package 1200 and the lens 1100 of FIG. 9B are the same as in FIG. 9A. However, in FIG. 9A, the reflective layer 1300a is disposed along the surface of the second region 1130 of the lens 1100 to have a uniform thickness. On the other hand, in this embodiment, the reflective layer 1300b is flatly disposed on the second region 1130 of the lens 110 to have a uniform thickness such that edges of the reflective layer 1300b are in contact with edges of the second region 1130 of the lens 1100 and a central region of the reflective layer 1300b is spaced from a central region of the second region 1130 of the lens 1100. The thickness of the reflective layer 1300b is not limited thereto. At least one part of the reflective layer 1300b may be thinner or thicker than the other parts.

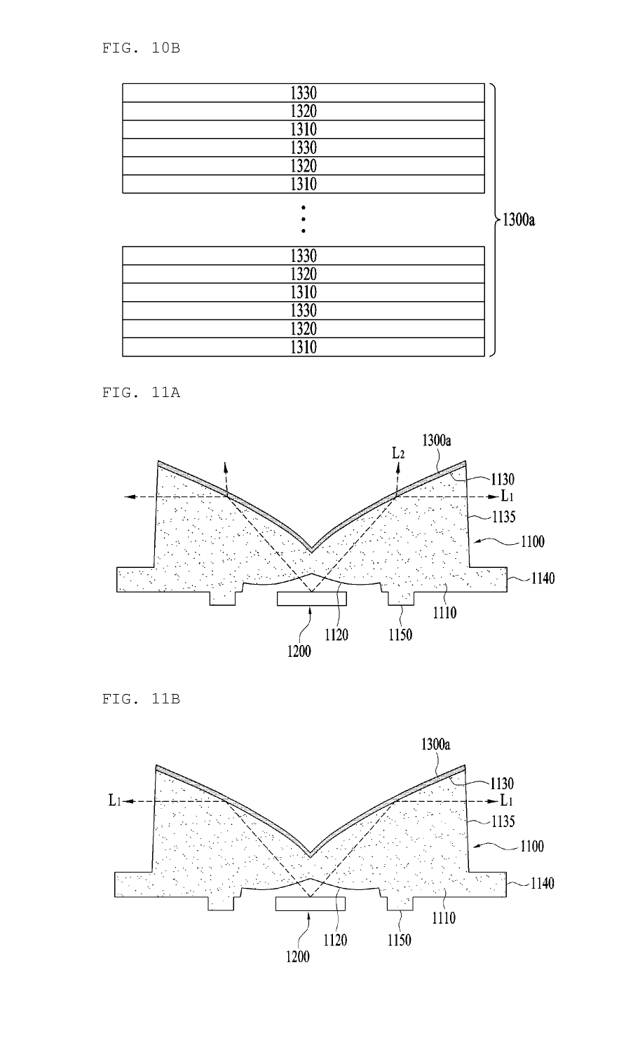

FIGS. 10A and 10B are views illustrating reflective layers according to embodiments of FIGS. 9A and 9B, respectively.

In FIG. 10a, the reflective layer 1300a may include a first layer 1310 and a second layer 1320 which are alternately arranged one above another at least once. The first layer 1310 and the second layer 1320 may include TiO₂ and SiO₂, respectively. For example, TiO₂ having a refractive index of 2.4 may be used as the first layer 1310. SiO₂ having a refractive index of 1.4 to 1.45 may be used as the second layer 1320. Herein, when a pair of a first layer 1310 and a second layer 1320 is stacked 39 times, the DBR having a thickness of about 3.11 micrometers may be formed.

The first layer 1310 and the second layer 1320 may be disposed to include SiO₂, SiₓO_{y}, AlAs, GaAs, AlₓIn_{y}P, and GaₓIn_{y}P rather than the above described combination. For example, the first layer 1310 and the second layer 1320 may include a combination of SiO₂/Si, AlAs/GaAs, Al_{0.5}In_{0.5}P/GaAS, Al_{0.5}In_{0.5}P/Ga_{0.5}In_{0.5}P, respectively.

In FIG. 10B, the reflective layer 1300a may include a first layer 1310, a second layer 1320, and a third layer 1330 which are alternately arranged. The first layer 1310, the second layer 1320, and the third layer 1330 may include GaN, GaP, SiO₂, RuO₂, and Ag. For example, GaP may be used as the first layer 1310, SiO₂ may be used as the second layer 1320, and Ag may be used as the third layer 1330. Herein, the reflective layer 1300a may function as the ODR.

In another example, GaN may be used as the first layer 1310, RuO₂ may be used as the second layer 1320, SiO₂ may be used as the third layer 1330, and Ag may be used as a fourth layer 1340. Herein, the reflective layer 1300a may function as the ODR.

The reflective layer 1300a in the embodiments illustrated in FIGS. 10A and 10B may function as the DBR or the ODR according to composition of the layers included therein.

FIGS. 11A and 11B illustrate paths of light of the light-emitting device modules of FIGS. 9A and 9B, respectively.

In FIG. 11A, the reflective layer 1300a may function as the DBR. Light emitted from the light-emitting device package 1200, namely, a light source, is incident on the lens 1100 and then is reflected from the reflective layer 1300a. Herein, a part of light may pass through the reflective layer 1300a. FIG. 11A illustrates light L1 reflected from the reflective layer 1300a and light L2 passing through the reflective layer 1300a, respectively.

In FIG. 11B, the reflective layer 1300a may function as the ODR. Light emitted from the light-emitting device package 1200, namely, a light source, is incident on the lens 1100 and then is completely reflected from the reflective layer 1300a. FIG. 11B illustrates light L1 reflected from the reflective layer 1300a.

The reflective layer 1300a respectively functioning as the DBR and the ODR in FIGS. 11A and 11B directly contacts the lens 1100. However, as illustrated in FIG. 9B, the reflective layer 1300a may be disposed to contact only the edges of the lens 1100. Herein, the reflective layer 1300a may function as the DBR and the ODR.

A size of the lens and a detailed structure of region “A” of FIG. 9A may be identical to the lens and the structure of “A” illustrated in FIGS. 2A to 2F. In addition, perspective views and a cross-sectional view of the lens of FIGS. 9A and 9B may be identical to the perspective views and the cross-sectional view of FIGS. 3A to 3C.

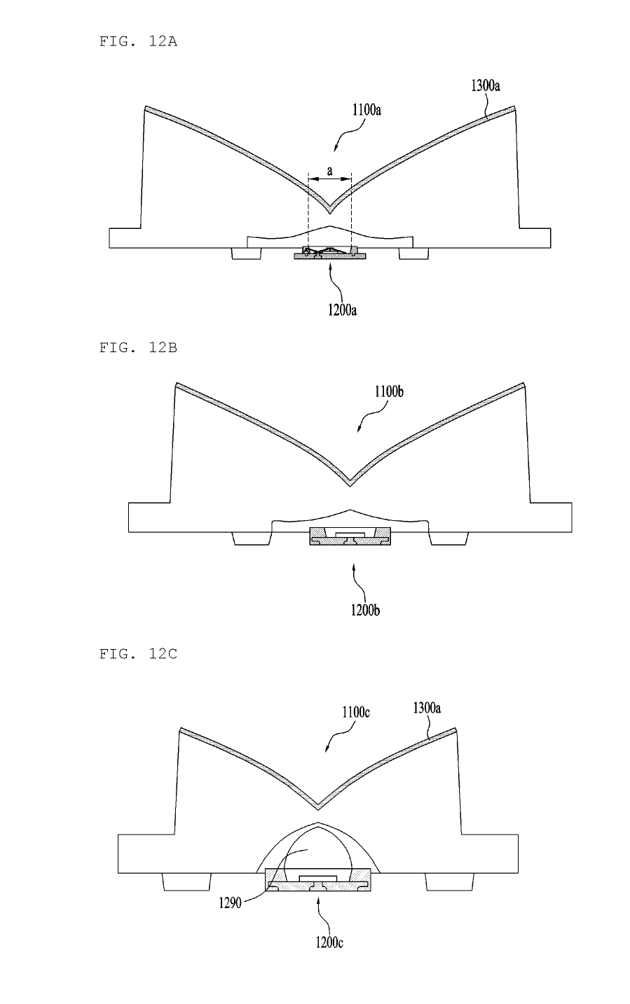

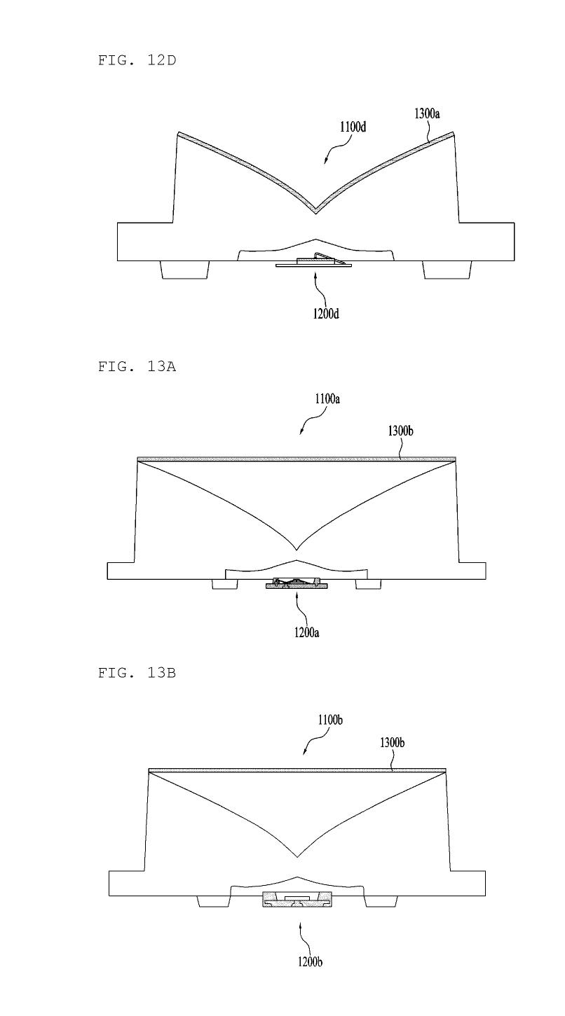

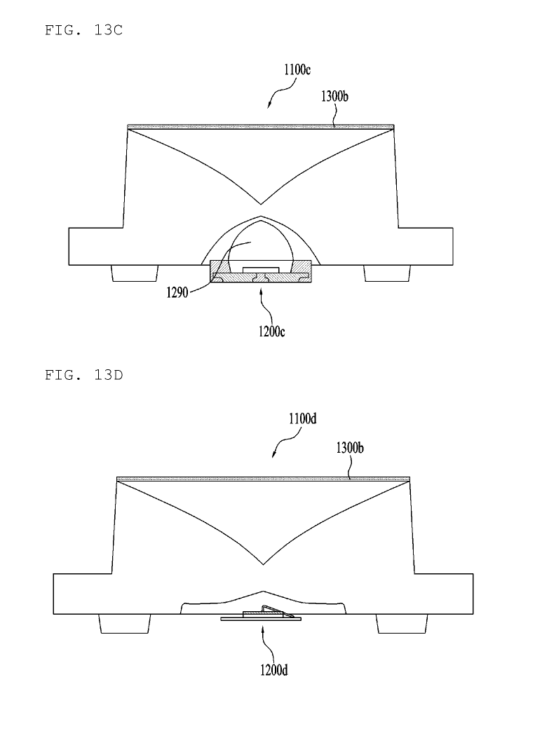

FIGS. 12A to 12D and FIGS. 13A to 13D are views illustrating various embodiments of the lenses of FIGS. 9A and 9B.

In FIGS. 12A to 12D, surface contact is provided between a reflective layer 1300a and a surface of a lens.

FIG. 12A illustrates a light-emitting device package 1200a including the lens 1100a. The light-emitting device package 1200a is inserted into the concave part formed at the light incident surface of the lower part of the lens 1100a. The horizontal light-emitting device may be disposed at the light-emitting device package 1200a. The molding part may surround the light-emitting device in the light-emitting device package 1200a to protect the light-emitting device. The fluorescent substance may be included in the molding part to change the wavelength of light emitted from the light-emitting device in the entire region where light of the light-emitting device package 1200a is emitted. The vertical light-emitting device may be disposed at the light-emitting device package 1200a rather than the horizontal light-emitting device, without being limited thereto.

FIG. 12B illustrates a light-emitting device package 1200b including a lens 1100b. The light-emitting device package 1200b is inserted into the concave part formed at the light incident surface of the lower part of the lens 1100b. The size of the concave part formed at the light incident surface may be identical to or different from the size of the concave part of FIG. 12A. The flip chip type light-emitting device may be disposed at the light-emitting device package 1200b.

FIG. 12C illustrates a light-emitting device package 1200c including a lens 1100c. This embodiment differs from the above-described embodiments in that the conic lens 1290 is disposed below the lens 1100c. A horizontal light-emitting device, a vertical light-emitting device, or a flip chip light-emitting device may be disposed at the light-emitting device package 1200c. The conic lens 1290 is disposed on the light incident surface of the concave part and the lens 1100c is disposed on the conic lens 1290. The concave part is formed at the light incident surface of the lens 1100c. The light-emitting device package 1200c and the conic lens 1290 may be inserted into the concave part such that the size of the concave part may be greater than the concave part of the above-described embodiments.

A detailed structure of the conic lens 1290 may be identical to the conic lens illustrated in FIG. 7A.

In FIG. 12D, a light-emitting device package 1200d may have a chip on board (COB) type. For example, the light-emitting device may be disposed on a pair of a first lead frame and a second lead frame functioning as a substrate. The fluorescent substance may be formed on the light-emitting device using a conformal coating method. The light-emitting device package 1200d may be inserted into the concave part formed at the light incident surface of the lower part of the lens 1100d.

The embodiments illustrated in FIGS. 13A to 13D are partially identical to the embodiments illustrated in FIGS. 12A to 12D, but differ from the embodiments of FIGS. 12A to 12D in that line contact between the reflective layer 1300b and edges of the surface of the lens is provided.

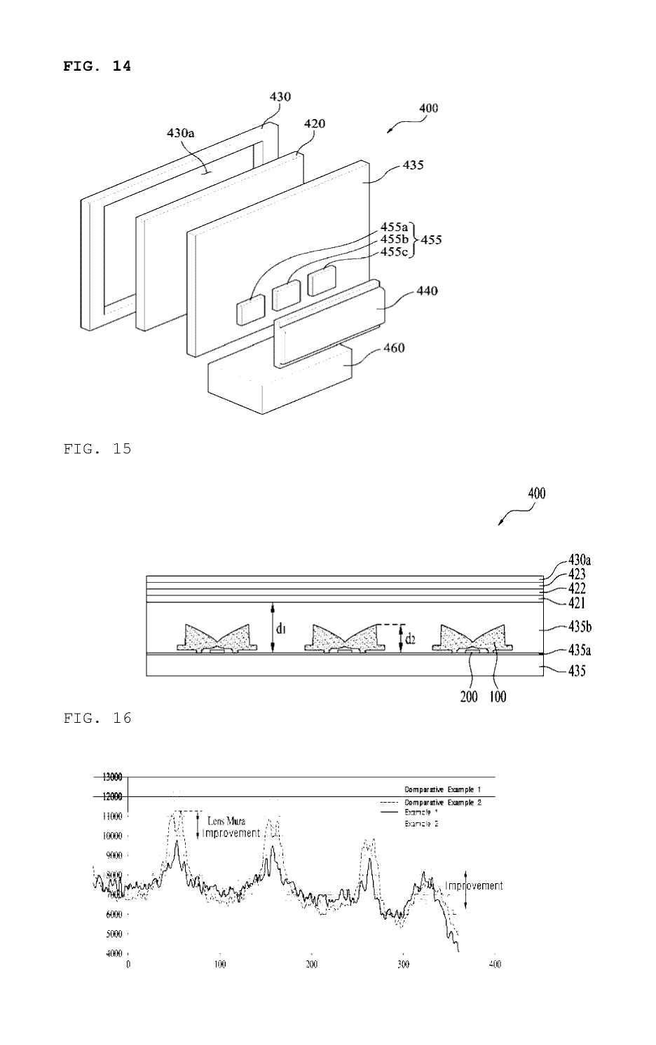

FIGS. 14 and 15 are views illustrating a display device including the light-emitting device module.

The display device 400 according to the illustrated embodiment includes a bottom cover 435, an optical sheet 420 facing the bottom cover 435, and a light-emitting device module disposed on the bottom cover 435 while being spaced from the optical sheet 420.

In FIG. 14, a driver 455 and a driver cover 440 encapsulating the driver 455 may be disposed at the bottom cover 435 of the display device 400.

A front cover 430 may include a front panel (not shown) formed of a transparent material for penetration of light. The front panel is spaced from a liquid crystal panel 430a to protect the liquid crystal panel 430a. Light emitted from the optical sheet 420 may be displayed at the liquid crystal panel 430a such that an image may be seen.

The bottom cover 435 may be connected to the front cover 430 to protect the optical sheet 420 and the liquid crystal panel 430a.

The driver 455 may be disposed at one side of the bottom cover 435.

The driver 455 may include a driving controller 455a, a main board 455b, and a power supply 455c. The driving controller 455a may be a time controller. The driving controller 455a is a driver for controlling a driving time at each driver IC of the liquid crystal panel 430a. The main board 455b is a driver for transferring V sync, H sync, and R, G, B resolution signals to the timing controller. The power supply 455c is a driver for applying power to the liquid crystal panel 430a.

The driver 455 may be surrounded by the driver cover 440 disposed at the bottom cover 435.

A plurality of holes is formed at the bottom cover 435 to connect the liquid crystal panel 430a to the driver 455. A stand 460 may be disposed to support the display device 400.

In FIG. 15, a reflective sheet 435a is disposed at a surface of the bottom cover 435. A light-emitting device package 200 is disposed on the reflective sheet 435a. A lens 100 is disposed at a front surface of the light-emitting device package 200. The light-emitting device module including the light-emitting device package 200 and the lens 100 is identical to the above-described light-emitting device package 200 and lens 100.

As described above, when light emitted from the light-emitting device package 200 is emitted through the lens 100, a luminous view angle is laterally widened. Light may be transferred through a light transmission region 435b to the optical sheet 421 to 423.

Light passing through the optical sheet 421 to 423 may head to the liquid crystal panel 430a.

In FIG. 15, a distance d1 between the reflective sheet 435a and the optical sheet 421 may be 10 to 15 millimeters. A height d2 of the light-emitting device package 200 including the lens 100 may be about 7 millimeters. The height d3 may be less than the distance d1 between the reflective sheet 435a and the optical sheet 421.

As described above, due to the lens, light emitted from the light-emitting device module sufficiently proceeds toward the side surface. Thereby, although the distance d1 between the reflective sheet 435a and the optical sheet 421 is narrowed to 15 millimeters or less, optical interference and generation of mura may be prevented. Since the height of the light-emitting device package 200 including lens 100 is about 7 millimeters, the distance d1 between the reflective sheet 435a and the optical sheet 421 is 10 millimeters or more. Thereby, damage due to collision between the optical sheet 421 and the lens 100 may be prevented.

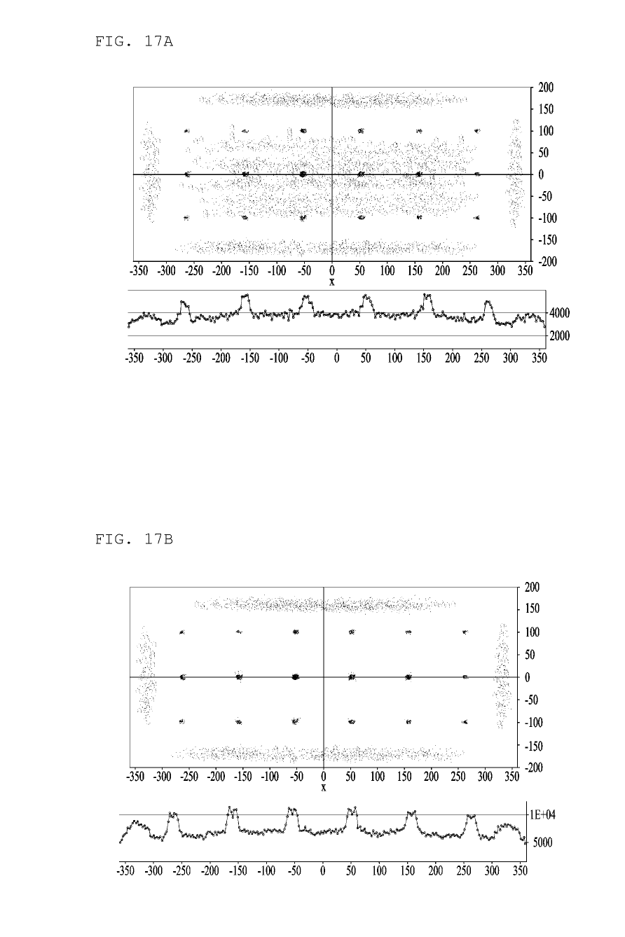

FIG. 16 is a view illustrating improvement of mura in the light-emitting device module according to embodiments.

In FIG. 16, a horizontal axis shows distances spaced from a central region of one backlight unit in the backlight unit, and a vertical axis shows measured light intensity emitted from each light source.

Comparative examples 1 and 2 of the conventional light-emitting device module generate mura, in which light is intensively generated at one point, for example an upper part of the lens. In the case of the light-emitting module according to Examples 1 and 2, as described above, a luminous view angle is widened using the lens according to the embodiments of the present invention, thereby decreasing generation of mura.

Furthermore, the left side of FIG. 16 is a region corresponding to a central region of the light-emitting device module in one backlight unit. The right side of FIG. 16 is a region corresponding to an edge region of the light-emitting device module. Accordingly, light intensity of the central region is greater than light intensity of the edge region. Additionally, dark part improvement which is designated as “improvement” in FIG. 16 will be described in FIGS. 17A and 17B.

FIGS. 17A and 17B are views illustrating improvement of a dark part in one backlight unit of the display device according to embodiments. A horizontal axis and a vertical axis show a position at each backlight unit.

FIG. 17a is a view showing luminance of a backlight unit at which a direct type light-emitting device module as described above is disposed. FIG. 17B is a view showing luminance of a backlight unit at which a conventional direct type light-emitting device module is disposed.

In the backlight unit of FIG. 17b, an area marked by a vertical rod at the right side of FIG. 17b is a dark part measured as a pink color group where light intensity is comparatively low. When the light-emitting device module according to the above-described embodiments is used, a luminous view angle is improved. Thereby, the dark part is reduced in comparison with the conventional backlight unit.

Although embodiments have been described with reference to a number of illustrative embodiments thereof, it should be understood that numerous other modifications and embodiments can be devised by those skilled in the art that will fall within the spirit and scope of the principles of this disclosure.

For example, various variations and modifications are possible in the component parts and/or arrangements of the subject combination arrangement within the scope of the disclosure, the drawings and the appended claims.

1-20. (canceled)

21. A lens for changing a path of light incident from a light source, the lens comprising:
a first region facing the light source, the first region having a concave part formed thereon; and
a second region facing the first region, the second region having a central part which is concave toward the first region, wherein:
the concave part has a surface comprising a (1-1)th region facing a center of the light source, a (1-3)th region at an edge thereof, and a (1-2)th region between the (1-1)th region and the (1-3)th region,
the (1-1)th region, the (1-2)th region, and the (1-3)th region have different curvatures,
the (1-1)th region, the (1-2)th region, and the (1-3)th region have different refraction angles, and
the refraction angle of light which passes through the (1-2)th region after being emitted from the light source is largest.

22. The lens according to claim 21, wherein the (1-1)th region is disposed at 0 to 45 degrees about a central axis, and the axis extends from the light source to a center of the second region.

23. The lens according to claim 21, wherein the (1-2)th region is disposed at 30 to 80 degrees about a central axis, and the axis extends from the light source to a center of the second region.

24. The lens according to claim 21, wherein the (1-3)th region is disposed at 60 to 90 degrees about a central axis, and the axis extends from the light source to a center of the second region.

25. The lens according to claim 21, wherein the (1-1)th region, the (1-2)th region, and the (1-3)th region have positive curvatures or negative curvatures.

26. The lens according to claim 21, wherein the (1-1)th region and the (1-3) the region have positive curvatures, and the (1-2)th region has a negative curvature.

27. The lens according to claim 21, wherein the (1-1)th region and the (1-3) the region have negative curvatures, and the (1-2)th region has a positive curvature.

28. The lens according to claim 21, wherein a ratio of a height of the lens to a height difference between an uppermost point and a lowermost point of the second region is more than 1:0.7 and less than 1:1.

29. A lens changing a path of light incident from a light source, the lens comprising:
a first region facing the light source, the first region having a concave part formed thereon; and
a second region facing the first region, the second region having a central part which is concave toward the first region, wherein:
the concave part has a surface comprising a (1-1)th region facing a center of the light source, a (1-3)th region at an edge thereof, and a (1-2)th region between the (1-1)th region and the (1-3)th region,
the (1-1)th region, the (1-2)th region, and the (1-3)th region have different refraction angles, and
wherein the refraction angle of light which passes through the (1-3)th region after being emitted from the light source is smallest.

30. The lens according to claim 29, wherein light passing through the (1-1)th region after being emitted from the light source is refracted toward a central axis.

31. The lens according to claim 29, wherein light passing through the (1-2)th region after being emitted from the light source is refracted toward a central axis.

32. The lens according to claim 29, wherein light passing through the (1-3)th region after being emitted from the light source is refracted toward a central axis.

33. The lens according to claim 29, wherein the refraction angle of light which passes through the (1-2)th region after being emitted from the light source is largest.

34. The lens according to claim 29, wherein, among light proceeding to the second region after being refracted at the first region, an angle between light passing through the (1-1)th region and an axis is smallest.

35. The lens according to claim 29, wherein, among light proceeding to the second region after being refracted at the first region, an angle between light passing through the (1-3)th region and an axis is largest.

36. A light-emitting device module comprising:
a body;
a first frame and a second frame disposed on the body;
a light-emitting device disposed at a body, the light-emitting device being electrically connected to the first frame and the second frame;
a molding part surrounding the light-emitting device; and
a lens changing a path of light incident from the light source,
wherein a reflective layer is disposed on a light emitting surface of the lens, and
the reflective layer is disposed on an entire region of the light emitting surface of the lens.

37. The light-emitting device module according to claim 36, the lens is a conic lens.

38. The light-emitting device module according to claim 37, wherein the lens comprises:
a first region facing the light source, the first region having a concave part formed thereon; and
a second region facing the first region, the second region having a central part which is concave toward the first region, wherein:
the concave part has a surface comprising a (1-1)th region facing a center of the light source, a (1-3)th region at an edge thereof, and a (1-2)th region between the (1-1)th region and the (1-3)th region,
the (1-1)th region, the (1-2)th region, and the (1-3)th region have different curvatures, and
the whole of the body and the whole of the light emitting device are disposed in the concave part.

39. The light-emitting device module according to claim 37, wherein the lens comprises:
a first region facing the light source, the first region having a concave part formed thereon; and
a second region facing the first region, the second region having a central part which is concave toward the first region, wherein:
the concave part has a surface comprising a (1-1)th region facing a center of the light source, a (1-3)th region at an edge thereof, and a (1-2)th region between the (1-1)th region and the (1-2)th region, and
the (1-1)th region, the (1-2)th region, and the (1-3)th region have different refraction angles.

40. The light-emitting device module according to claim 37, wherein the reflective layer includes a distributed Bragg reflector (DBR) or an omni-directional reflector (ODR).
